(19) United States
(12) Patent Application Publication
(10) Pub. No.: US 2014/0251422 A1
(43) Pub. Date: Sep. 11, 2014

(54) SOLAR CELL WITH DOPING BLOCKS

(71) Applicant: Neo Solar Power Corp., Hsinchu City (TW)

(72) Inventors: CHENG-WEI LIU, HSINCHU CITY (TW); WEI-MING CHEN, HSINCHU CITY (TW); JUI-LIN WANG, HSINCHU CITY (TW)

(73) Assignee: Neo Solar Power Corp., Hsinchu City (TW)

(21) Appl. No.: 14/082,453

(22) Filed: Nov. 18, 2013

(30) Foreign Application Priority Data
Mar. 6, 2013 (TW) 102107893

(51) Int. Cl. H01L 31/048

(52) U.S. Cl. CPC H01L 31/048
USPC 136/256

(57) ABSTRACT

A solar cell with doping blocks is provided, which includes: a semiconductor substrate, an anti-reflection layer, a plurality of front electrodes, and a back electrode layer. The semiconductor substrate has a first surface, and a plurality of doping block layers is arranged under the first surface and spaced from each other. The anti-reflection layer is disposed on the doping block layer and the semiconductor substrate. The front electrodes penetrate the anti-reflection layer and are arranged on the doping block layers. The back electrode layer is disposed on a second surface of the semiconductor substrate.

### CROSS-REFERENCES TO RELATED APPLICATIONS

This non-provisional application claims priority under 35 U.S.C. §119(a) on Patent Application No. 102107893 filed in Taiwan, R.O.C. on Mar. 6, 2013, the entire contents of which are hereby incorporated by reference.

### BACKGROUND

1. Technical Field

The disclosure relates to a solar cell, and more particularly to a solar cell with doping blocks, the doping block can be strip-type or block-type.

2. Related Art

Due to the increasing shortage of fossil fuels, people are more and more aware of the importance of environmental protection. Consequently, in recent years people have actively studied technologies related to alternative energy sources and renewable energy sources, hoping to reduce human dependence on fossil energy and influence on the environment due to the use of fossil energy. Among the many technologies of alternative energy sources and renewable energy sources, the solar cell is most anticipated. The main reason for this is that the solar cell can directly convert solar energy into electric energy, and no harmful substances such as carbon dioxide or nitride are generated during the power generation process, so no pollution is caused to the environment.

Generally speaking, in the conventional silicon solar cells, counter-doping is performed on a surface of a semiconductor substrate in diffusion or ion implantation manner, so as to form a doped layer and manufacture an electrode. When light impinges on the silicon solar cell from the outside, a silicon board generates free electron-hole pairs as being excited by photons, the electrons and the holes moving to electrodes of two sides of solar cell respectively, so as to generate electric energy; at this time, if a load circuit or an electrical device connects to the said electrodes, electric energy can be provided to enable the circuit or the device to perform driving.

According to different materials, the solar cells are classified into silicon (mono-crystalline silicon, multi-crystalline silicon, and amorphous silicon), solar cell, III-V compound semiconductor (GaAs, GaP, InP and so on), solar cell, II-VI compound semiconductor (CdS, CdSe, CdTe etc), solar cell, and organic semiconductor solar cell. At present, the mono-crystalline silicon and multi-crystalline silicon solar cells made of silicon are the mainstream solar cells, and the amorphous silicon can be applied to a thin film solar cell. The solar cells made of different materials may be different in processes, properties of matched materials, and cell structures (layer structures), due to different material properties thereof.

Please refer to FIG. 1, which is a schematic view of a common crystalline solar cell including a semiconductor substrate 10, an anti-reflection layer 30, front electrodes 40, P+ doped layer 50, and a back electrode 60. The semiconductor substrate 10 has a first surface, and a doped layer 24 is arranged under the first surface. The anti-reflection layer 30 is disposed on the doped layer 24, and used for reducing reflectivity of incident light. The front electrode 40 is disposed on the anti-reflection layer. The back electrode 60 is disposed on a second surface of the semiconductor substrate.

Generally, when solar cells are produced, due to the process factor the size of the solar cells is fixed, generally being 156 mm*156 mm. In some product applications, such a large-size solar cell is not required and the solar cell has to be divided into a plurality of small-size solar cells. Please refer to a P-N junction 100 in FIG. 2, in which the solar cell is cut into two parts along a cutting line 70 in FIG. 1, the severed solar cells have a leakage current generated at an edge end of the P-N junction 100 due to the defects on a junction of N-type and P-type edges caused by the cutting. As a result, the output power of the severed solar cell is reduced accordingly.

Therefore, how to solve the problem of the leakage current generated due to the defects on the junction of N-type and P-type edges is an important subject to be processed during miniaturization of the solar cells.

### SUMMARY

The present invention discloses a solar cell with doping blocks, which includes a semiconductor substrate, at least one anti-reflection layer, a plurality of front electrodes, and a back electrode layer. The semiconductor substrate has a first surface, a plurality of doping block layers is arranged under the first surface, wherein the first surface has a plurality of doping block layers which include the same dopant and the doping block layers are arranged at intervals. The anti-reflection layer is disposed on the doping block layers. The front electrodes are formed on the anti-reflection layer and the doping block layers, penetrating the anti-reflection layer. The back electrode layer is disposed on a second surface of the semiconductor substrate.

The present invention further discloses a strip-type solar cell, which includes a semiconductor substrate, an anti-reflection layer, at least one front electrode, and a back electrode layer. The semiconductor substrate of the present invention has a first surface and four lateral sides, wherein a strip-type doped layer is arranged under the first surface, and a gap is formed between the side of the strip-type doped layer and the lateral side of the semiconductor substrate. The anti-reflection layer is disposed on the strip-type doped layer. Furthermore, the front electrodes are formed on the anti-reflection layer and penetrate the anti-reflection layer, so as the front electrodes are contacting to the strip-type doped layer. The back electrode layer is disposed on a second surface of the semiconductor substrate.

The present invention further discloses a block-type solar cell, which includes a semiconductor substrate, an anti-reflection layer, at least one front electrode, and a back electrode layer. The semiconductor substrate of the present invention has a first surface and four lateral sides, wherein a doping block layer is arranged under the first surface, and a gap is formed between the side of the doping block layer and the side of the semiconductor substrate. In some embodiments, the first surface is further provided with at least one connection doped region, and the connection doped region is connected to a part of one lateral side of the doping block layer and the lateral side of the semiconductor substrate; the doping block layer and the connection doped region both include the same dopant. The anti-reflection layer is disposed on the doping block layer. The front electrodes are formed on the anti-reflection layer and penetrate the anti-reflection layer, so as the front electrodes are contacting to the strip-type doped layer. The back electrode layer is disposed on a second surface of the semiconductor substrate.

Therefore, the doping blocks of solar cell of the present invention are surrounding by the semiconductor substrate. Cutting several small solar cells from the solar cell with doping blocks along the cutting line in the semiconductor substrate between the doping blacks, the P-N junction will not be exposed. So the defect of P-N junction and current leakage of the cutting surface are prevent, and the small-size solar cells with doping block can keep high efficiency.

To make the objectives, features and advantages of the present invention more comprehensible, the disclosure is illustrated in detail below with reference to several preferred embodiments and the accompanying drawings.

### BRIEF DESCRIPTION OF THE DRAWINGS

The disclosure will become more fully understood from the detailed description given herein below for illustration only, and thus not limitative of the present invention, wherein:

FIG. 1 is a schematic sectional view of a solar cell in the prior art;

FIG. 2 is a schematic view showing that a leakage current is generated on a P-N junction caused when the solar cells is cut in the prior art;

FIG. 3 is a schematic view of a first embodiment of a solar cell with doping blocks of the present invention;

FIG. 4 is a schematic cutting view of the first embodiment of the solar cell with doping blocks of the present invention;

FIG. 5 is a schematic view of a second embodiment of a solar cell with doping blocks of the present invention;

FIG. 6A is a first front view of a solar cell with doping blocks of the present invention;

FIG. 6B is a sectional view of a strip-type solar cell cut along a cutting line in FIG. 6A of the present invention;

FIG. 7A is a second front view of a solar cell with doping blocks of the present invention;

FIG. 7B is a sectional view of a block-type solar cell cut along a cutting line in FIG. 7A of the present invention;

FIG. 8A is a third front view of a solar cell with doping blocks provided with a bus bar electrode of the present invention;

FIG. 8B is a third front view of a solar cell with doping blocks of the present invention;

FIG. 8C is a sectional view of a strip-type solar cell cut along a cutting line in FIG. 8B of the present invention;

FIG. 9A is a fourth front view of a solar cell with doping blocks provided with a bus bar electrode of the present invention;

FIG. 9B is a fourth front view of a solar cell with doping blocks of the present invention;

FIG. 9C is a view of the block-type solar cell cut along a cutting line in FIG. 9B of the present invention;

FIG. 9D is a side view of the block-type solar cell in FIG. 9C of the present invention; and

FIG. 10 is a fifth front view of a solar cell with doping blocks of the present invention.

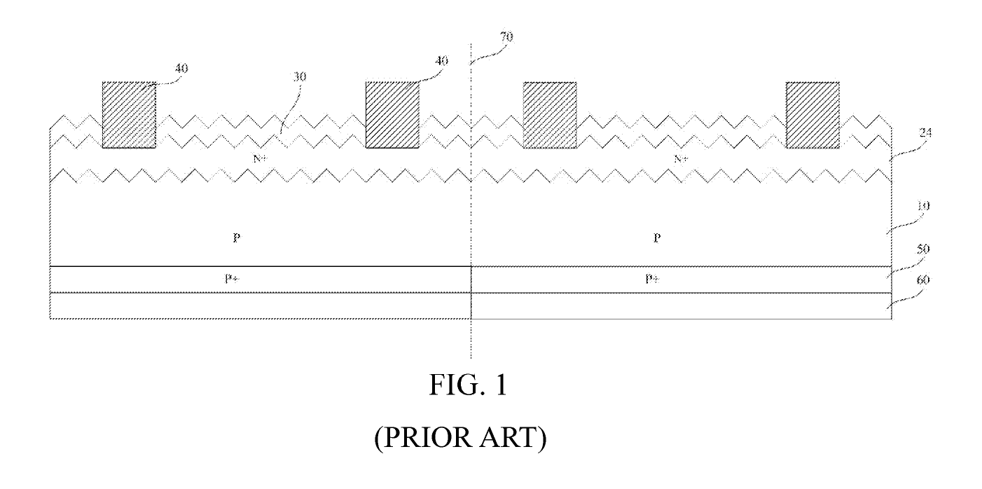

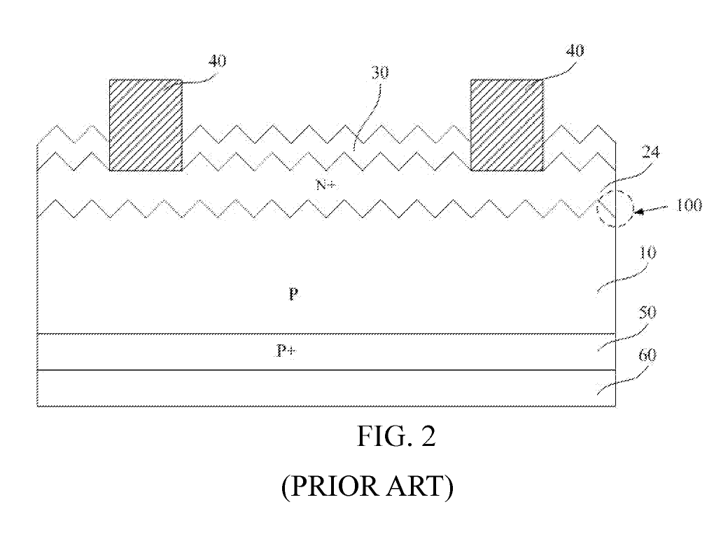

### DETAILED DESCRIPTION

Due to the solar cell with doping blocks of the present invention structured by several independent doping blocks, when the blocks are cut down into block pieces along the edge of the blocks, the cutting is performing in semiconductor substrate where without the P-N junction. Therefore, the solar cell with doping blocks of the present invention is able to produce multiple ‘block type solar cells’ by cutting along the edge of the doping blocks. Each of the block type solar cell pertains high efficiency as same as the solar cells with same process. The leakage current will not happen in the cutting surface of the solar cell with doping block of the present invention.

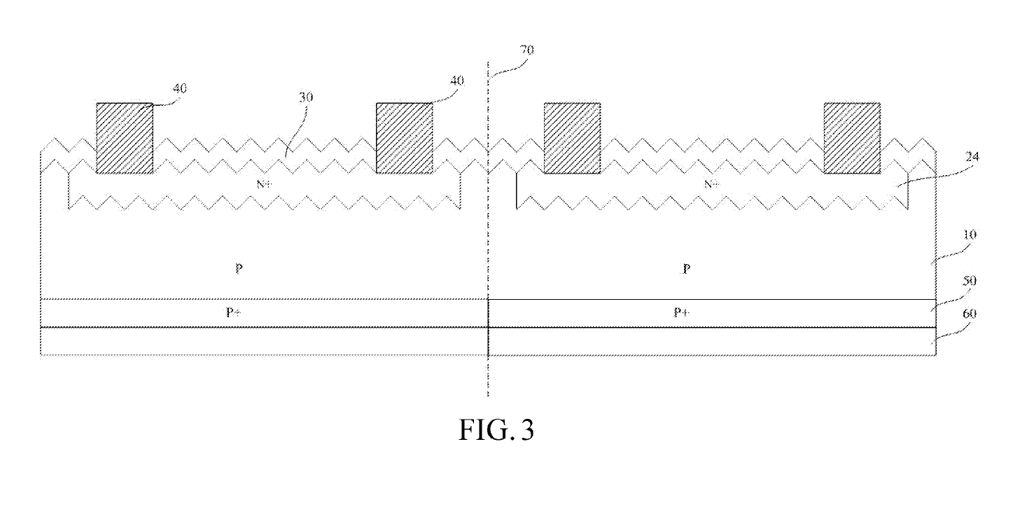

Referring to FIG. 3, which is a schematic view of a first embodiment of a solar cell with doping blocks. The solar cell with doping blocks includes a semiconductor substrate 10, an anti-reflection layer 30, a plurality of front electrodes 40, a P+ doped layer 50, and a back electrode layer 60. The semiconductor substrate 10 has a first surface and a second surface, wherein the first surface having a plurality of doping block layers 24 which include the same dopant, and the doping block layers 24 are spaced from each other. As aforementioned description, the plurality of doping block layers 24 is arranged under the first surface, and the doping block layers 24 are spaced from each other and doping block layers 24 are not mutually connected. The anti-reflection layer 30 is formed on the doping block layer 24 and the semiconductor substrate 10. The anti-reflection layer 30 includes multiple film layers to reduce reflectivity of incident light, in other embodiments, the anti-reflection layer 30 may be single film layer or a film layer with gradient refractive index. The front electrodes 40 are disposed on the doping block layers 24 and the anti-reflection layer 30, and the front electrodes 40 penetrate the anti-reflection layer 30 to contact to the doping block layers 24 The back electrode layer 60 is disposed on the second surface of the semiconductor substrate 10 which includes the P+ doped layer 50. In this embodiment, the first surface of the semiconductor substrate 10 is a textured surface, in another embodiment, the second surface may also be a non-textured surface. Likewise, in this embodiment, the back electrode layer 60 is disposed on the non-textured second surface of the semiconductor substrate 10; and in another embodiment, the second surface may also be a textured surface. Therefore, even if the second surface of the semiconductor substrate 10 is a textured surface, the back electrode layer 60 may still be disposed on the textured surface.

The semiconductor substrate 10 may be a photoelectric conversion substrate such as a mono-crystalline silicon substrate or a multi-crystalline silicon substrate. In this embodiment, the semiconductor substrate 10 is a P-type mono-crystalline silicon substrate; in another embodiment, the semiconductor substrate 10 is an N-type mono-crystalline silicon substrate. The semiconductor substrate 10 of this embodiment has a first surface (a front surface), being an incident surface, and has a second surface (a back surface), being a shadowy surface.

The doping block layer 24 is formed by performing counter-doping on the surface of the semiconductor substrate 10, the counter-doping may be performed in diffusion or ion implantation manner. For instance, if the semiconductor substrate 10 is the P-type semiconductor substrate, and the doping block layer 24 is formed by N-type dopant, for example but not limited to, phosphorus, arsenic, antimony, bismuth, or a combination of any two of the above; if the semiconductor substrate 10 is the N-type semiconductor substrate, the doping block layer 24 is formed by P-type dopant, for example but not limited to, boron, aluminum, gallium, indium, thallium, or a combination of any two of the above.

Referring to FIG. 3, the first surface of the semiconductor substrate 10 is the surface of the doping block layer 24, a bottom surface of the doping block layer 24 forms a P-N junction and a carrier depletion region will be formed. The depletion region provides a built-in electric field, and free electrons are moved toward to the N electrode and the holes are moved toward to the P electrode by the electric field in the depletion, thereby generating a current. At this time, power generated by the solar cell can be used as long as the two ends are connected through an externally added circuit.

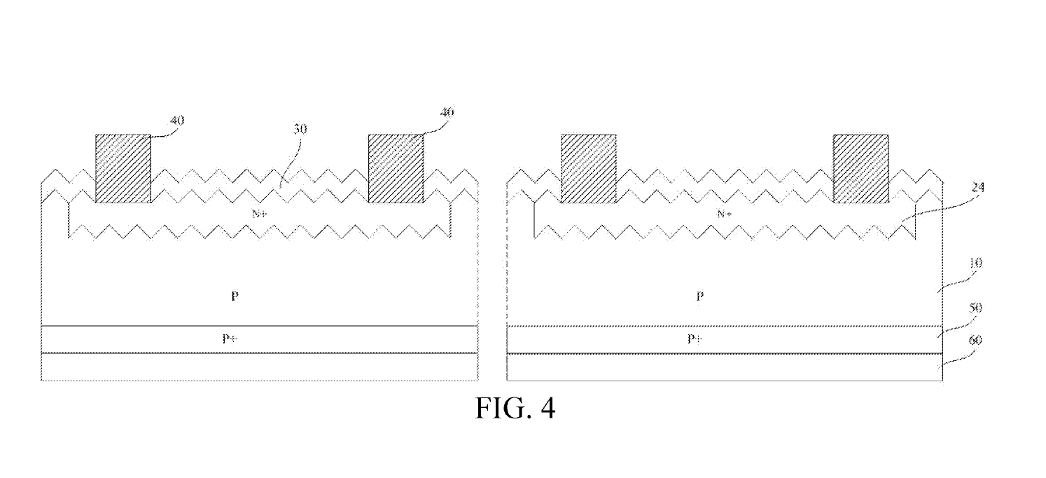

FIG. 3 shows a plurality of doping block layers 24 is arranged under the first surface of the semiconductor substrate 10, wherein the doping block layers 24 are formed in a block type and are spaced from each other by the semiconductor substrate 10 which without undergoing the counter-doping, so the doping block layers 24 are not connected to each other. When the solar cell with doping blocks of the present invention is cut, the cutting may be performed along the cutting line 70 of the semiconductor substrate 10 between the doping block layers 24. Because the cut partial semiconductor substrate 10 is a complete P-type or N-type semiconductor substrate (which is the P type in the embodiment shown in FIG. 3), the cutting face does not expose the P-N junction and so as the leakage current phenomenon is avoided. Please refer to FIG. 4, which is a result after the cutting in FIG. 3. In FIG. 4, two front electrodes 40 penetrate the anti-reflection layer 30 and are disposed on the doping block layer 24.

FIG. 4 shows a strip-type solar cell, which includes a semiconductor substrate 10, an anti-reflection layer 30, at least one front electrode 40, a P+ doped layer 50, and a back electrode layer 60. The semiconductor substrate 10 has a first surface and four lateral sides, a doping block layer 24 is arranged under the first surface, and a gap is formed between four lateral sides and the four lateral sides of the semiconductor substrate 10. The anti-reflection layer 30 is disposed on the doping block layer 24 and the semiconductor substrate 10, and the anti-reflection layer 30 at least includes one film, layer to reduce reflectivity of the incident light. The front electrode 40 penetrates the anti-reflection layer 30 and is disposed on the doping block layer 24. The back electrode layer 60 is disposed on a second surface of the semiconductor substrate 10 which includes the P+ doped layer 50.

The solar cell with doping blocks of the present invention, the solar cell may be cut into strip-type parts or small blocks. When reverse biases are applied on a surface electrode and the back electrode, the reduction of the leakage current can be obtained.

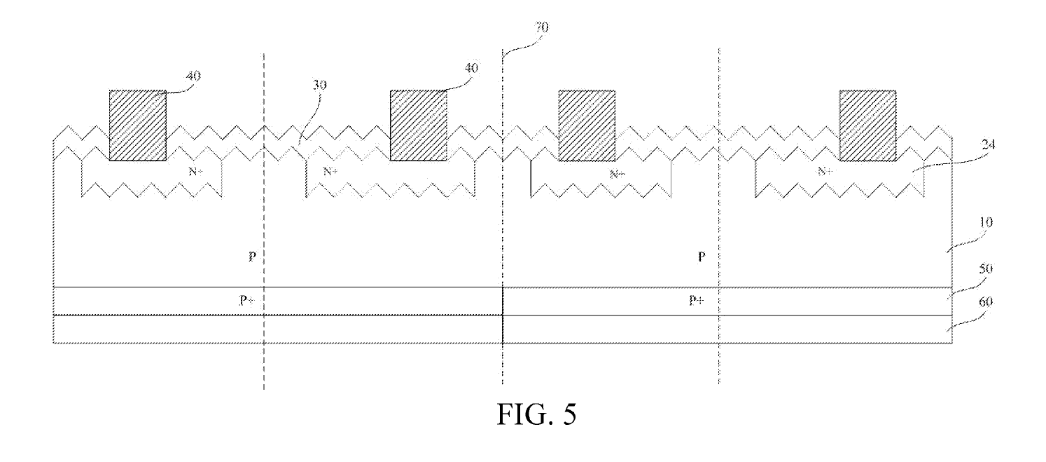

For the configuration of the electrode, at least one front electrode is arranged on each doped layer. Please refer to FIG. 5, which is a schematic view of an embodiment in which one front electrode 40 is disposed on each doping block layer 24. In the embodiment in FIG. 4, two front electrodes 40 are disposed on each doping block layer 24.

It should be noted that, the description of the foregoing embodiment is not intended to limit the number of the front electrodes on each doping block layer, and three, four, or more front electrodes may be disposed on the doped layer.

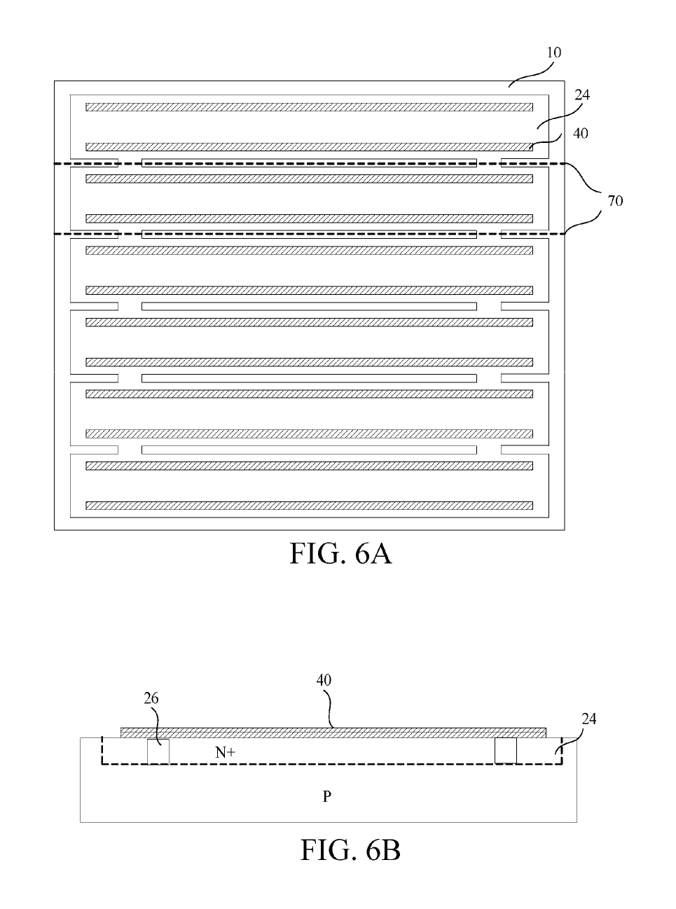

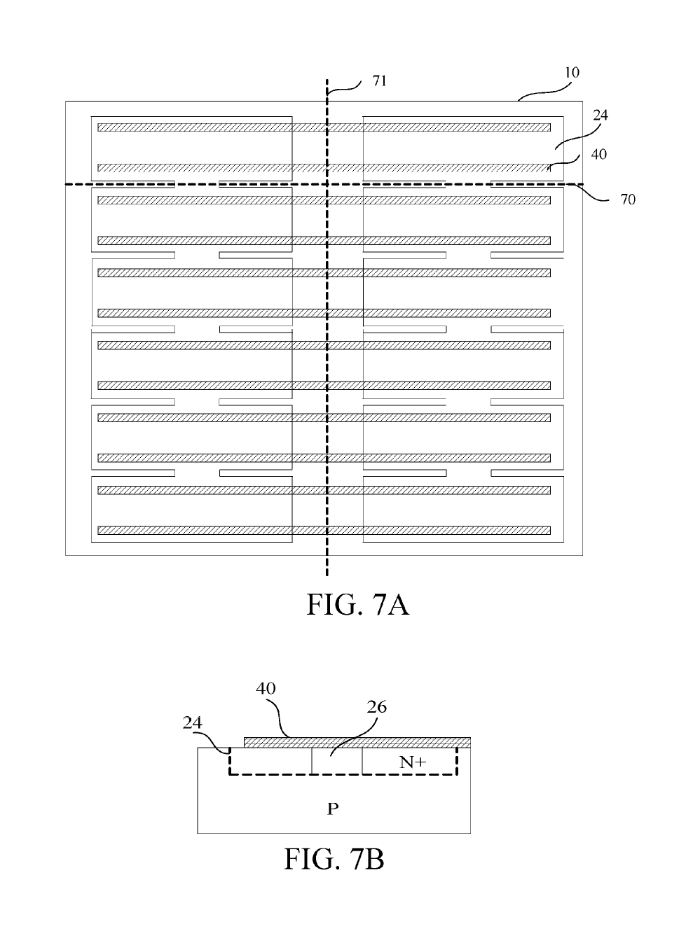

Then, FIG. 6A and FIG. 7A are respectively a first front view and a second front view showing the design of the doping block layer of the present invention. FIG. 6A is a front view of FIG. 3, and it indicates that the solar cell with doping blocks can be cut into strip-type parts. It can be seen from the structure of FIG. 6A that, a plurality of doping block layers 24 is arranged under the first surface of the semiconductor substrate 10, and the doping block layers 24 are spaced from each other; moreover, the doping block layers 24 are in a strip-type. FIG. 6B is a sectional view of a strip-type solar cell cut along the cutting line 70 in FIG. 6A of the present invention. It can be seen from FIG. 6B that, except the connection doped region 26, the P-N junction on the side view of the cut strip-type solar cell is greatly reduced. Therefore, the leakage current can be dramatically alleviated.

FIG. 7A shows that a plurality of doping block layers 24 is arranged under the first surface of the semiconductor substrate 10, and the doping block layers 24 are spaced from each other and not mutually connected; moreover, the doping block layers 24 are in a block shape, and may be cut into independent block-type solar cells along the cutting lines 70 and 71. FIG. 7B is a sectional view of the block-type solar cell cut along the cutting line 70, and the P-N junction exposed on the side of the severed block-type solar cell in FIG. 7B is greatly reduced. Therefore, the leakage current can be dramatically alleviated.

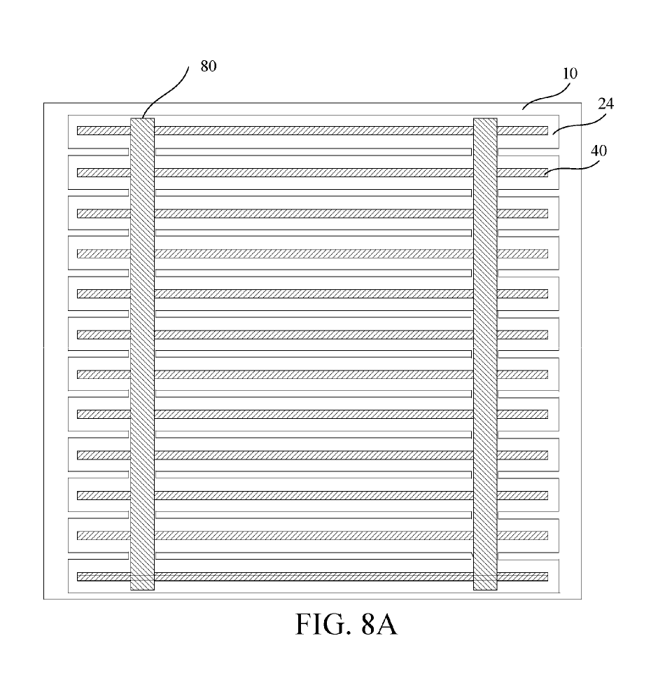

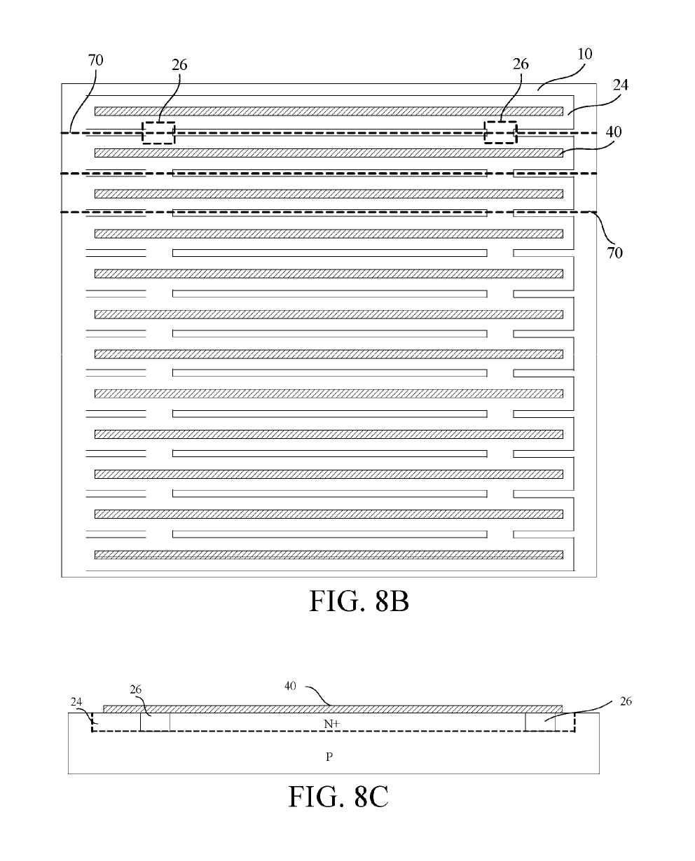

Then, Please refer to FIG. 8A, which is a third front view of a bus bar electrode in the design of the doping block layer of the present invention. The connection doped region 26 is arranged under the bus bar electrode 80 so that the adjacent doping block layers 24 are partially connected. Please refer to FIG. 8B, in which it can be seen from the structure that, a plurality of doping block layers 24 is arranged under the first surface of the semiconductor substrate 10, the doping block layers 24 are spaced from each other; a plurality of connection doped regions 26 is connected to parts of the adjacent doping block layers 24, and the connection doped regions 26 are formed of the same dopant as the doping block layers 24. The connection doped region 26 is arranged under the front electrode 40 so that the adjacent doping block layers 26 are partially connected. The doping block layers 24 may be cut along the cutting line 70 into independent strip-type solar cells. FIG. 8C is a sectional view of an strip-type solar cell cut along the cutting line in FIG. 8B of the present invention, and the P-N junction exposed on the side of the cut strip-type solar cell in FIG. 8C is greatly reduced. Therefore, the leakage current can be dramatically alleviated.

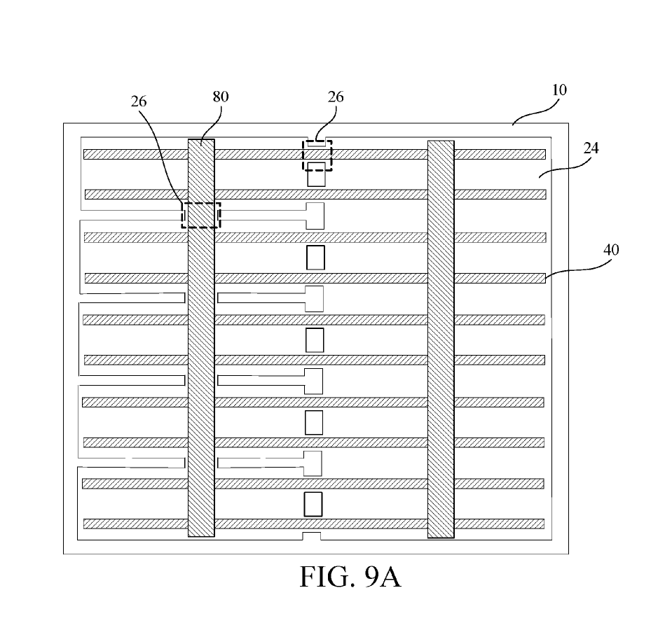

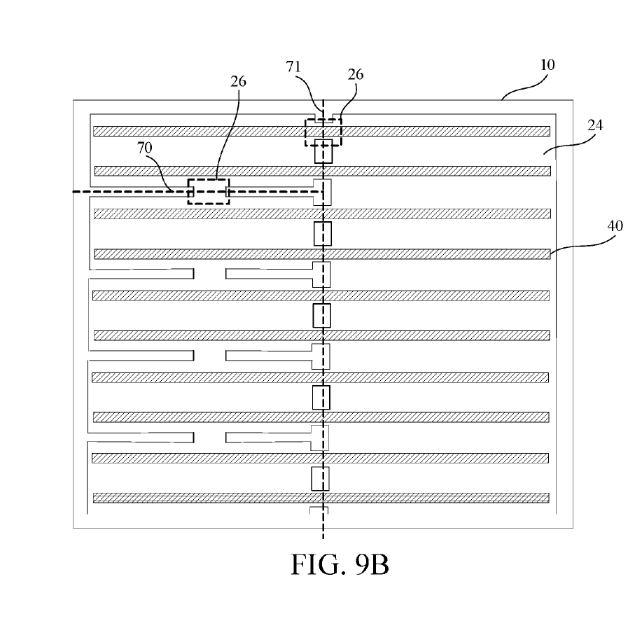

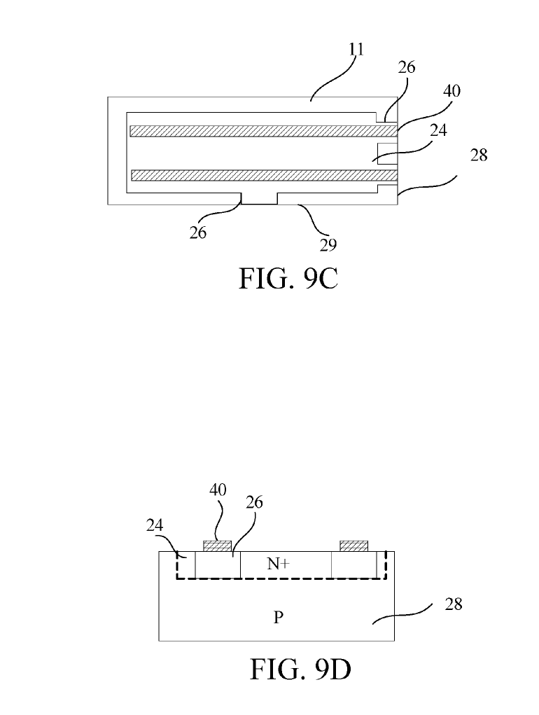

Please refer to FIG. 9A, which is a fourth front view of a bus bar electrode in the design of the doping block layer of the present invention. The connection doped region 26 is connected to a bus electrode 80 or a lower portion of the front electrode 40 so that the adjacent doping block layers 24 are partially connected. Please refer to FIG. 9B, in which it can be seen from the structure that, a plurality of doping block layers 24 is arranged under the first surface of the semiconductor substrate 10, and the doping block layers 24 are spaced from each other; a plurality of connection doped regions 26 is connected to parts of the adjacent doping block layers 24, and the connection doped regions 26 are formed of the same dopant as the doping block layers 24. The connection doped region 26 is arranged under the front electrode 40 so that the adjacent doping block layers 26 are partially connected. The doping block layers 24 may be cut along the cutting lines 70 and 71 into independent block-type solar cells.

FIG. 9C is a view of a block-type solar cell cut along the cutting line 70 in FIG. 9B of the present invention. It can be seen from FIG. 9C that, the severed block-type solar cell 11 forms four lateral sides, a lateral side 28 includes the connection doped region 26 and the front electrode 40, and another lateral side 29 includes the connection doped region 26. In other words, in the severed block-type solar cell 11, the connection doped region 26 is connected to a part of one of the four lateral sides of the doping block layer 24 and the lateral side 28 of the semiconductor substrate. FIG. 9D is a side view of the block-type solar cell in FIG. 9C of the present invention.

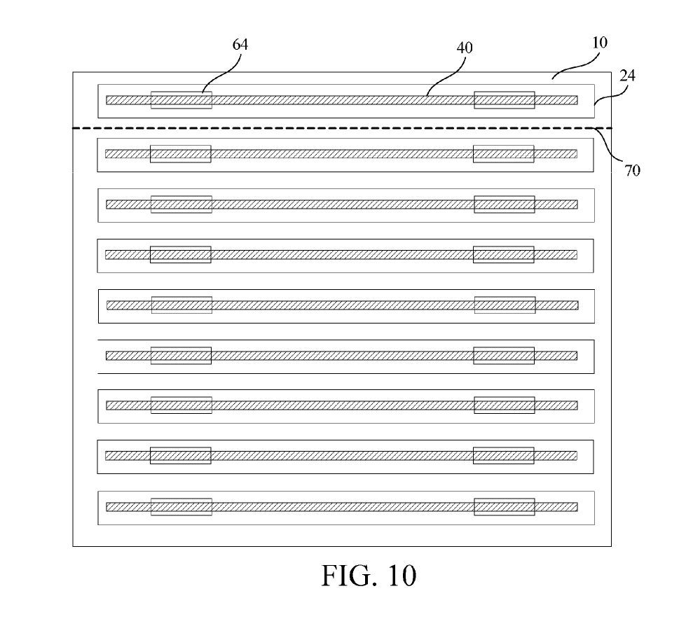

Please refer to FIG. 10, which is a fifth front view of the design of the doping block layer of the present invention. It can be seen from the structure that, a plurality of strip-type doping block layers 24 is arranged under the first surface of the semiconductor substrate 10, and the strip-type doping block layers 24 are spaced from each other. One front electrode 40 is disposed on each strip-type doping block layer 24, and two island soldering electrodes 64 are further disposed on each front electrode 40. In another embodiment, each front electrode 40 may be provided with at least one island soldering electrode 64. The solar cell with doping blocks in FIG. 10 is cut along the cutting lines 70 between the doping block layers 24, and strip-type solar cells are obtained and can be used according to special requirements on the size. A gap is formed between four lateral sides of the doping block layer 24 and the four lateral sides of the semiconductor substrate, that is, the semiconductor substrate 10 encircles the strip-type doping block layer 24, so the P-N junction is not exposed on the cutting surface, thereby avoiding the leakage current phenomenon. In this embodiment, the soldering electrode 64 is in an island design, and is different from the design of the soldering electrode in FIG. 8B and FIG. 9B; therefore, the connection doped region 26 does not need to be arranged.

In another embodiment of the present invention, the design of the doping block layer of the present invention may also be applied in solar cell architecture with a selective emitter.

According to the aforementioned description, the doping block layer is surrounded by the non-doped region of the semiconductor substrate, when the substrate is cut along the cutting line 70 in non-doped region the defect on the junction of the N+ and P-type edges can be reduced. By means of the present invention, the efficacy of avoiding a leakage current generated due to the defect on the edge junction can be achieved.

While the disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A solar cell with doping blocks, comprising:
a semiconductor substrate, having a first surface, wherein the first surface has a plurality of doping block layers which comprise the same dopant and the doping block layers are arranged at intervals;
at least one anti-reflection layer disposed on the doping block layers;
a plurality of front electrodes formed on the anti-reflection layer and the doping block layers, penetrating the anti-reflection layer; and
a back electrode layer disposed on a second surface of the semiconductor substrate.

2. The solar cell with doping blocks according to claim 1, wherein the doping block layer under each front electrode further comprises a heavily doped layer.

3. The solar cell with doping blocks according to claim 1, wherein the semiconductor substrate is a P-type semiconductor substrate or an N-type semiconductor substrate.

4. The solar cell with doping blocks according to claim 3, wherein when the semiconductor substrate is the P-type semiconductor substrate, a dopant of the doped layer is of N type.

5. The solar cell with doping blocks according to claim 4, wherein the N-type dopant is phosphorus, arsenic, antimony, bismuth, or a combination thereof.

6. The solar cell with doping blocks according to claim 3, wherein when the semiconductor substrate is the N-type semiconductor substrate, a dopant of the doped layer is of P type.

7. The solar cell with doping blocks according to claim 6, wherein the P-type dopant is boron, aluminum, gallium, indium, thallium or a combination thereof.

8. The solar cell with doping blocks according to claim 1, wherein the semiconductor substrate is a mono-crystalline silicon substrate or a multi-crystalline silicon substrate.

9. The solar cell with doping blocks according to claim 1, wherein the doping block layers are strip-type.

10. The solar cell with doping blocks according to claim 1, wherein the doping block layers are disconnected from each other.

11. The solar cell with doping blocks according to claim 1, further comprising a plurality of connection doped regions, connected to parts of the adjacent doping block layers, wherein the connection doped regions and the doping block layers comprise the same dopant.

12. The solar cell with doping blocks according to claim 11, wherein the connection doped regions are arranged under a bus bar electrode so that the adjacent doping block layers are partially connected by the connection doped regions.

13. The solar cell with doping blocks according to claim 11, wherein the connection doped regions are arranged under the front electrodes so that the adjacent doping block layers are partially connected.

14. A strip-type solar cell, comprising:
a semiconductor substrate, having a first surface and four lateral sides, wherein a strip-type doped layer is arranged under the first surface, and a gap is formed between four lateral sides of the strip-type doped layer and four lateral sides of the semiconductor substrate;
at least one anti-reflection layer disposed on the strip-type doped layer;
at least one front electrode formed on the anti-reflection layer and the strip-type doped layer, penetrating the anti-reflection layer; and
a back electrode layer, disposed on a second surface of the semiconductor substrate.

15. The strip-type solar cell according to claim 14, wherein the strip-type doped layer under each front electrode further comprises a strip-type heavily doped layer.

16. The strip-type solar cell according to claim 14, wherein the semiconductor substrate is a P-type semiconductor substrate or an N-type semiconductor substrate.

17. The strip-type solar cell according to claim 14, wherein when the semiconductor substrate is the P-type semiconductor substrate, the dopant of the strip-type doped layer is of N type.

18. The strip-type solar cell according to claim 17, wherein the N-type dopant is phosphorus, arsenic, antimony, bismuth, or a combination thereof.

19. The strip-type solar cell according to claim 14, wherein when the semiconductor substrate is the N-type semiconductor substrate, the dopant of the strip-type doped layer is of P type.

20. The strip-type solar cell according to claim 19, wherein the P-type dopant is boron, aluminum, gallium, indium, thallium, or a combination thereof.

21. The strip-type solar cell according to claim 14, wherein the semiconductor substrate is a mono-crystalline silicon substrate or a multi-crystalline silicon substrate.

22. The strip-type doped solar cell according to claim 14, further comprising:
a plurality of connection doped regions, connected to a part of one of four lateral sides of the strip-type doped layer and a lateral side of the semiconductor substrate, wherein the connection doped regions and the strip-type doped layer comprise the same dopant.

23. The strip-type solar cell according to claim 22, wherein the connection doped regions are arranged under a bus bar electrode.

24. The strip-type solar cell according to claim 22, wherein the connection doped regions are arranged under the front electrodes.

25. A block-type solar cell, comprising:
a semiconductor substrate, having a first surface and four lateral sides, wherein a doping block layer is arranged under the first surface, a gap is formed between four lateral sides of the doping block layer and four lateral sides of the semiconductor substrate; the first surface is further provided with at least one connection doped region, and the connection doped region is connected to apart of one of the four lateral sides of the doping block layer and the lateral side of the semiconductor substrate; the doping block layer and the connection doped region both comprise the same dopant;
at least one anti-reflection layer disposed on the doping block layer;
at least one front electrode penetrating the anti-reflection layer and arranged on doping block layer; and
a back electrode layer, disposed on a second surface of the semiconductor substrate.

26. The block-type solar cell according to claim 25, wherein the connection doped regions are arranged under a bus bar electrode.

27. The block-type solar cell according to claim 25, wherein the connection doped region is arranged under the front electrodes.
